(19) United States
(12) Patent Application Publication
(10) Pub. No.: US 2022/0342294 A1
(43) Pub. Date: Oct. 27, 2022

(54) MASK BLANK, PHASE SHIFT MASK, AND METHOD OF MANUFACTURING SEMICONDUCTOR DEVICE

(71) Applicant: HOYA CORPORATION, Tokyo (JP)

(72) Inventors: Hiroaki SHISHIDO, Tokyo (JP); Hitoshi MAEDA, Tokyo (JP)

(73) Assignee: HOYA CORPORATION, Tokyo (JP)

(21) Appl. No.: 17/634,481

(22) PCT Filed: Sep. 1, 2020
(86) PCT No.: PCT/JP2020/033040

§ 371 Date: Feb. 10, 2022

(30) Foreign Application Priority Data
Sep. 25, 2019 (JP) 2019-173996

(51) Int. Cl. G03F 1/32

(52) U.S. Cl. CPC G03F 1/32

(57) ABSTRACT

Provided is a mask blank including a phase shift film.

The mask blank includes a phase shift film on a main surface of a transparent substrate, the phase shift film contains silicon, oxygen, and nitrogen, a ratio of a nitrogen content [atom %] to a silicon content [atom %] in the phase shift film is 0.20 or more and 0.52 or less, a ratio of an oxygen content [atom %] to a silicon content [atom %] in the phase shift film is 1.16 or more and 1.70 or less, a refractive index n of the phase shift film to a wavelength of an exposure light of an ArF excimer laser is 1.7 or more and 2.0 or less, and an extinction coefficient k is 0.05 or less.

### CROSS-REFERENCE TO RELATED APPLICATIONS

This application is the National Stage of International Application No. PCT/JP2020/033040, filed Sep. 1, 2020, which claims priority to Japanese Patent Application No. 2019-173996, filed Sep. 25, 2019, and the contents of which is incorporated by reference.

### TECHNICAL FIELD

The present disclosure relates to a mask blank for a phase shift mask, a phase shift mask, and a method of manufacturing a semiconductor device.

### BACKGROUND ART

In the manufacturing process of a semiconductor device, a fine pattern is formed using a photolithography method. A number of transfer masks are usually used to form the fine pattern. In order to miniaturize a pattern of a semiconductor device, in addition to miniaturization of a mask pattern formed in a transfer mask, it is necessary to shorten a wavelength of an exposure light source used in photolithography. In recent years, application of an ArF excimer laser (wavelength 193 nm) is increasing as an exposure light source in the manufacture of semiconductor devices.

A chromeless phase shift mask (CPL mask) is one type of a transfer mask. A configuration where an etching stopper film is provided on a transparent substrate, and a phase shift film containing silicon and oxygen and having substantially the same transmittance as that of the transparent substrate is provided on the etching stopper film is known as a CPL mask. Further, a CPL mask is known which has a dug-down portion and a non-dug-down portion on a substrate that is transparent to an exposure light and configuring a transfer pattern with the dug-down portion and the non-dug-down portion.

For example, Patent Document 1 discloses an optical mask blank having, on a transparent substrate, an etching stopper layer, a phase shift layer pattern, and a light shielding layer pattern in this order, in which a silicon nitride layer (Si₃N₄ film) as the etching stopper layer and a SiO₂ film as the phase shift layer are provided in this order, and having thereon a low reflectance chromium light shielding film, as the light shielding layer, having a chromium oxide layer, a metal chromium layer, and a chromium oxide layer stacked in this order.

Further, Patent Document 2 discloses a photomask blank for a chromeless phase shift mask in which, in a chromeless phase shift mask provided with a dug-down portion on a substrate that is transparent to an exposure light to adjust a phase of a transmitting light, a light shielding film provided at a portion adjacent to the substrate dug-down portion or a periphery of the substrate includes a film A including, as a main ingredient, MoSi or an MoSi compound which is a material that can be etched in an etching process using etching gas mainly including fluorine-based gas.

### PRIOR ART PUBLICATIONS

### Patent Documents

[Patent Document 1]
Japanese Patent Application Publication H07-128839

[Patent Document 2]
Japanese Patent Application Publication 2007-241136

### SUMMARY OF THE DISCLOSURE

### Problems to be Solved by the Disclosure

A CPL mask is configured to produce a transfer image only by a strong phase shift effect generated between an exposure light transmitted through a dug-down portion and an exposure light transmitted through a non-dug-down portion in a region where the dug-down portion is formed basically in plan view. The smaller the difference between a transmittance of a dug-down portion and a transmittance of a non-dug-down portion to an exposure light, the stronger the phase shift effect. In the case of a CPL mask, in order to enhance a CD uniformity of the transferred image, it is desirable to reduce the difference in each in-plane phase shift effect between a dug-down portion and non-dug-down portion. Namely, it is desirable that the dug-down portions provided in the plane have the same depth. A dug-down portion of a conventional CPL mask is formed by dry-etching a transparent substrate to a predetermined depth. However, it is difficult to create the same depth for each dug-down portion in a transparent substrate by controlling the etching time, etc. of dry etching. Further, it is difficult to create a dug-down portion to have a flat bottom surface with dry etching.

In order to solve these problems, an attempt was made to provide a phase shift film consisting of silicon and oxygen via an etching stopper film on a transparent substrate as disclosed in Patent Document 1. In other words, as an alternative to a dug-down portion of a conventional CPL mask, the inventors examined forming a fine pattern by dry-etching a phase shift film consisting of silicon and oxygen. In the case of a CPL mask in which an ArF excimer laser light is applied as an exposure light (hereafter referred to as ArF exposure light), a phase shift film consisting of silicon and oxygen is required to have a thickness of at least 170 nm or more in order to produce a desired phase shift effect. When a transparent substrate which is a same structure is dug to form a dug-down portion, a pattern of the dug-down portion hardly collapses or falls off even if the dug-down portion is deep. On the other hand, in forming a fine pattern in a phase shift film provided on an etching stopper film, since adhesion between the etching stopper film and the pattern of the phase shift film is not as high, there has been a problem that a pattern of a phase shift film tends to collapse or fall off. This problem similarly occurs when a phase shift film is provided in contact with a transparent substrate.

The present disclosure was made to solve the conventional problems. An aspect of the present disclosure is to provide a mask blank including a phase shift film in which a transmittance to an exposure light of an ArF excimer laser can be enhanced and a film thickness necessary to secure a desired phase difference can be controlled to be small. Further, an aspect of the present disclosure is to provide a phase shift mask including a phase shift film that can enhance a transmittance to an exposure light of an ArF excimer laser and having a transfer pattern in which a film thickness necessary to secure a desired phase difference can be controlled to be small. The present disclosure provides a method of manufacturing a semiconductor device using such a phase shift mask.

### Means for Solving the Problem

As means for solving the above problems, the present disclosure includes the following configurations.

(Configuration 1)

A mask blank including a phase shift film on a main surface of a transparent substrate,

in which the phase shift film contains silicon, oxygen, and nitrogen,

in which a ratio of a nitrogen content [atom %] to a silicon content [atom %] of the phase shift film is 0.20 or more and 0.52 or less,

in which a ratio of an oxygen content [atom %] to a silicon content [atom %] of the phase shift film is 1.16 or more and 1.70 or less,

in which a refractive index n of the phase shift film to a wavelength of an exposure light of an ArF excimer laser is 1.7 or more and 2.0 or less, and

in which an extinction coefficient k of the phase shift film to the wavelength of the exposure light is 0.05 or less.

(Configuration 2)

The mask blank according to Configuration 1, in which a ratio of nitrogen content [atom %] to an oxygen content [atom %] of the phase shift film is 0.12 or more and 0.45 or less.

(Configuration 3)

The mask blank according to Configuration 1 or 2, in which a silicon content of the phase shift film is 30 atom % or more.

(Configuration 4)

The mask blank according to any of Configurations 1 to 3, in which the phase shift film has a function to transmit the exposure light at a transmittance of 70% or more, and a function to generate a phase difference of 150 degrees or more and 210 degrees or less between the exposure light transmitted through the phase shift film and an exposure light transmitted through the air for a same distance as a thickness of the phase shift film.

(Configuration 5)

The mask blank according to any of Configurations 1 to 4, in which the phase shift film has a thickness of 140 nm or less.

(Configuration 6)

The mask blank according to any of Configurations 1 to 5 including a light shielding film on the phase shift film.

(Configuration 7)

A phase shift mask including a phase shift film having a transfer pattern on a main surface of a transparent substrate,

in which the phase shift film contains silicon, oxygen, and nitrogen,

in which a ratio of a nitrogen content [atom %] to a silicon content [atom %] of the phase shift film is 0.20 or more and 0.52 or less,

in which a ratio of an oxygen content [atom %] to a silicon content [atom %] of the phase shift film is 1.16 or more and 1.70 or less,

in which a refractive index n of the phase shift film to a wavelength of an exposure light of an ArF excimer laser is 1.7 or more and 2.0 or less, and

in which an extinction coefficient k of the phase shift film to the wavelength of the exposure light is 0.05 or less.

(Configuration 8)

The phase shift mask according to Configuration 7, in which a ratio of a nitrogen content [atom %] to an oxygen content [atom %] of the phase shift film is 0.12 or more and 0.45 or less.

(Configuration 9)

The phase shift mask according to Configuration 7 or 8, in which the phase shift film has a silicon content of 30 atom % or more.

(Configuration 10)

The phase shift mask according to any of Configurations 7 to 9, in which the phase shift film has a function to transmit the exposure light at a transmittance of 70% or more, and a function to generate a phase difference of 150 degrees or more and 210 degrees or less between the exposure light transmitted through the phase shift film and an exposure light transmitted through the air for a same distance as a thickness of the phase shift film.

(Configuration 11)

The phase shift mask according to any of Configurations 7 to 10, in which the phase shift film has a thickness of 140 nm or less.

(Configuration 12)

The phase shift mask according to any of Configurations 7 to 11 including a light shielding film having a pattern with a light shielding band on the phase shift film.

(Configuration 13)

A method of manufacturing a semiconductor device including a step of transferring a transfer pattern to a resist film on a semiconductor substrate by exposure using the phase shift mask according to Configuration 12.

### Effect of the Disclosure

The mask blank of the present disclosure having the above configuration includes a phase shift film on a main surface of a transparent substrate, featured in that the phase shift film contains silicon, oxygen, and nitrogen, a ratio of a nitrogen content [atom %] to a silicon content [atom %] in the phase shift film being 0.20 or more and 0.52 or less, a ratio of an oxygen content [atom %] to a silicon content [atom %] in the phase shift film being 1.16 or more and 1.70 or less, a refractive index n of the phase shift film to a wavelength of an exposure light of an ArF excimer laser being 1.7 or more and 2.0 or less, and an extinction coefficient k of the phase shift film to the wavelength of the exposure light being 0.05 or less. Therefore, it is possible to manufacture a phase mask blank including a phase shift film that can enhance a transmittance to an exposure light of an ArF excimer laser and having a transfer pattern in which a film thickness necessary to secure a desired phase difference can be controlled to be small. Moreover, in manufacturing a semiconductor device using the phase shift mask, a pattern can be transferred to a resist film, etc. on the semiconductor device with excellent precision.

### BRIEF DESCRIPTION OF THE DRAWINGS

FIG. 1 is a schematic cross-sectional view of an embodiment of a mask blank.

FIGS. 2A-2G are schematic cross-sectional views showing a manufacturing step of a phase shift mask.

### EMBODIMENTS FOR CARRYING OUT THE DISCLOSURE

The embodiments of the present disclosure are explained below. First, the background of the present disclosure is explained. In forming a dug-down portion of a CPL mask with a phase shift film, the phase shift film is desired to have a high transmittance (e.g., 70% or more) to an ArF exposure light in order to produce a strong phase shift effect. From the viewpoint of a transmittance alone, SiO₂ of the same material system as that of the transparent substrate is suitable as a material of a phase shift film. However, a phase shift film formed of SiO₂ has a small refractive index n to an ArF exposure light. To obtain a phase shift effect generated from the phase shift film, it is necessary to significantly increase the film thickness.

From the viewpoint of increasing a refractive index n of a phase shift film, it is preferable that a phase shift film consisting of silicon and oxygen further contains a metal element. However, the degree of increase in an extinction coefficient k due to the inclusion of a metal element in a phase shift film is large, and thus it is difficult to secure a high transmittance. On the other hand, including nitrogen in a phase shift film consisting of silicon and oxygen (i.e., forming a phase shift film from an SiON-based material mainly containing silicon, oxygen, and nitrogen) can increase a refractive index n of the phase shift film, although not as remarkable as to include a metal element. However, while a refractive index n of the phase shift film gradually increases as a nitrogen content of a phase shift film increases, an extinction coefficient k of the phase shift film tends to gradually decrease in conjunction with the increase. Namely, a phase shift film of an SiON-based material has a trade-off relationship where a film thickness required to produce a strong phase shift effect decreases as a nitrogen content increases, but a transmittance decreases. For this reason, in forming a phase shift film from an SiON-based material, it is important to find a range of a nitrogen content and an oxygen content that can secure a high transmittance to an ArF exposure light while reducing a film thickness necessary to produce a strong phase shift effect.

On the other hand, a phase shift film is generally formed by a sputtering method since a phase shift film preferably has an amorphous structure or a microcrystal structure. In forming a phase shift film by reactive sputtering, an internal structure of the phase shift film can be made rather sparse (with numerous gaps) by adjusting pressure in a film forming chamber and sputtering voltage. By making an internal structure of a phase shift film sparse, it is possible to increase a transmittance to an exposure light to some extent. It seems that a reduction in ArF transmittance caused by increasing a nitrogen content of an SiON-based material film can be restrained through the procedure given above. However, such an SiON-based material film has low physical durability and low chemical resistance of the pattern after forming a fine pattern by dry etching. Such an SiON-based material film is not suitable for a phase shift film.

As a result of further diligent examination, the inventors found a suitable phase shift film to replace a dug-down portion of a CPL mask. Namely, the phase shift film is formed of a material containing silicon, nitrogen, and oxygen. In addition thereto, a ratio of a nitrogen content [atom %] to a silicon content [atom %] of the phase shift film is 0.20 or more and 0.52 or less, and a ratio of a nitrogen content [atom %] to an oxygen content [atom %] is 1.16 or more and 1.70 or less. Further a refractive index n of the phase shift film to an ArF exposure light is set to 1.7 or more and 2.0 or less, and an extinction coefficient k of an ArF exposure light to 0.05 or less. With such a configuration, it is possible to produce a strong phase shift effect with a relatively thin film thickness while a phase shift film has a dense internal structure with a high transmittance to an ArF exposure light.

Detailed configurations of the present disclosure given above are explained based on the drawings. Identical reference numerals are applied to similar components in the drawings.

<Mask Blank>

A mask blank according to an embodiment of the present disclosure is a mask blank used for manufacturing a CPL (Chromeless Phase Lithography) mask, namely, a chromeless phase shift mask. A CPL mask is a phase shift mask of a type in which basically no light shielding film is provided in a transfer pattern forming region excluding a region of a large pattern, and a transfer pattern is formed by a dug-down portion and a non-dug-down portion of a transparent substrate.

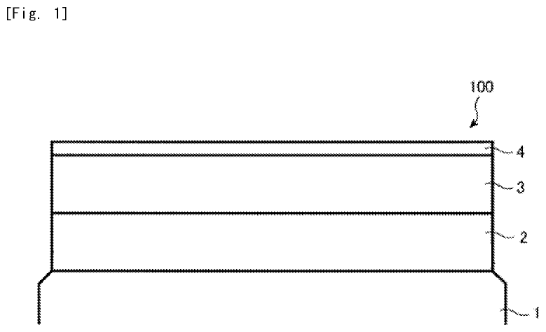

FIG. 1 shows a schematic configuration of an embodiment of a mask blank. A mask blank 100 shown in FIG. 1 has a configuration where a phase shift film 2, a light shielding film 3, and a hard mask film 4 are stacked in this order on one main surface of a transparent substrate 1. The mask blank 100 can have a configuration without the hard mask film 4 as desired. Further, the mask blank 100 can have a configuration where a resist film is stacked on the hard mask film 4 as desired. The detail of major elements of the mask blank 100 is explained below.

[Transparent Substrate]

The transparent substrate 1 is formed of materials having a good transmittance to an exposure light used in an exposure step in lithography. As such materials, synthetic quartz glass, aluminosilicate glass, soda-lime glass, low thermal expansion glass (SiO₂—TiO₂ glass, etc.), and various other glass substrates can be used. Particularly, a substrate using synthetic quartz glass has high transmittance to an ArF excimer laser light (wavelength: about 193 nm), which can be used preferably as the transparent substrate 1 of the mask blank 100.

The exposure step in lithography as used herein refers to an exposure step of lithography using a phase shift mask produced by using the mask blank 100, and the exposure light hereinafter indicates an ArF excimer laser light (wavelength 193 nm), unless otherwise specified.

A refractive index of the material forming the transparent substrate 1 to an exposure light is preferably 1.5 or more and 1.6 or less, more preferably 1.52 or more and 1.59 or less, and even more preferably 1.54 or more and 1.58 or less.

[Phase Shift Film]

The phase shift film 2 preferably has a function to transmit an exposure light at a transmittance of 70% or more. This is to generate a sufficient phase shift effect between an exposure light transmitted through the interior of the phase shift film 2 and an exposure light transmitted through the air. The phase shift film 2 more preferably has a function to transmit an exposure light at a transmittance of 75% or more. Further, a transmittance of the phase shift film 2 to an exposure light is preferably 93% or less, and more preferably 90% or less. This is to hold the film thickness of the phase shift film 2 within a proper range to secure optical performance.

To obtain a proper phase shift effect, it is desirable for the phase shift film 2 to be adjusted to have a function to generate a phase difference of 150 degrees or more and 210 degrees or less between an exposure light transmitted through the phase shift film 2 and an exposure light that transmitted through the air for the same distance as a thickness of the phase shift film 2. The phase difference in the phase shift film 2 is preferably 155 degrees or more, and more preferably 160 degrees or more. On the other hand, the phase difference of the phase shift film 2 is preferably 200 degrees or less, and more preferably 190 degrees or less.

To at least satisfy each condition of the transmittance and the phase difference in the entire phase shift film 2, a refractive index n to a wavelength of an exposure light (hereafter simply referred to as refractive index n) is preferably 1.7 or more, and more preferably 1.75 or more. Further, a refractive index n of the phase shift film 2 is preferably 2.0 or less, and more preferably 1.98 or less. An extinction coefficient k of the phase shift film 2 to a wavelength of an exposure light (hereafter simply referred to as extinction coefficient k) is preferably 0.05 or less, and more preferably 0.04 or less. Further, an extinction coefficient k of the phase shift film 2 is preferably 0.005 or more, and more preferably 0.007 or more. A refractive index n and an extinction coefficient k of the phase shift film 2 are values derived by regarding the entire phase shift film 2 as a single, optically uniform layer.

A refractive index n and an extinction coefficient k of a thin film including the phase shift film 2 are not determined only by the composition of the thin film. Film density and crystal state of the thin film are also factors that affect a refractive index n and an extinction coefficient k. Therefore, the conditions in forming a thin film by reactive sputtering are adjusted so that the thin film has desired refractive index n and extinction coefficient k. For allowing the phase shift film 2 to have a refractive index n and an extinction coefficient k within the above range, not only a ratio of mixed gas of noble gas and reactive gas (oxygen gas, nitrogen gas, etc.) is adjusted in forming a film by reactive sputtering, but various other adjustments are made upon forming a film by reactive sputtering, such as pressure in a film forming chamber, power applied to a sputtering target, and positional relationship such as distance between a target and the transparent substrate 1. These film forming conditions are unique to film forming apparatuses, and are adjusted properly so that a thin film to be formed has desired refractive index n and extinction coefficient k. However, for the above reason, the phase shift film 2 is not excessively adjusted which renders its internal structure sparse.

To reduce the occurrence of collapse of patterns, the phase shift film 2 preferably has a film thickness of 140 nm or less. Further, a film thickness of the phase shift film 2 is preferably 95 nm or more, and more preferably 100 nm or more to secure a function to generate a desired phase difference.

The phase shift film 2 preferably contains silicon, nitrogen, and oxygen. Total content of silicon, nitrogen, and oxygen of the phase shift film 2 is preferably 97 atom % or more, more preferably 98 atom % or more, and even more preferably 99 atom % or more. It is preferable that a metal element content of the phase shift film 2 is less than 1 atom %, and more preferably lower detection limit or less when composition analysis was performed using an X-ray photoelectron spectroscopy. This is because including a metal element in the phase shift film 2 causes an increase in an extinction coefficient k.

The phase shift film 2 is preferably formed of a material consisting of silicon, oxygen, and nitrogen, or can be formed of a material consisting of silicon, oxygen, nitrogen, and one or more elements selected from a metalloid element and a non-metallic element. This is because a metalloid element and a non-metallic element, up to a certain content, slightly affect the optical properties of the phase shift film 2. On the other hand, the phase shift film 2 can contain any metalloid elements. Among these metalloid elements, it is preferable to include one or more elements selected from boron, germanium, antimony, and tellurium, since enhancement in conductivity of silicon to be used as a target in forming the phase shift film 2 by sputtering can be expected. The phase shift film 2 can be patterned through dry etching using fluorine-based gas, and has sufficient etching selectivity to a light shielding film 3 to be mentioned below.

An oxygen content of the phase shift film 2 is preferably 42 atom % or more, and more preferably 43 atom % or more in view of enhancing a transmittance. An oxygen content of the phase shift film 2 is preferably 60 atom % or less, and more preferably 58 atom % or less in view of restraining a reduction of a refractive index n.

Further, a nitrogen content of the phase shift film 2 is preferably 6 atom % or more, and more preferably 7 atom % or more in view of enhancing a refractive index n. A nitrogen content of the phase shift film 2 is preferably 22 atom % or less, and more preferably 20 atom % or less in view of restraining an increase of an extinction coefficient k.

Further, a silicon content of the phase shift film 2 is preferably 30 atom % or more, and more preferably 33 atom % or more in view of enhancing physical durability and chemical resistance. A silicon content of the phase shift film 2 is preferably 40 atom % or less, and more preferably 38 atom % or less in view of enhancing a transmittance.

N/Si ratio of the phase shift film 2 is preferably 0.20 or more, and more preferably 0.22 or more in view of enhancing a refractive index n. On the other hand, the N/Si ratio is preferably 0.52 or less, and more preferably 0.51 or less in view of restraining an increase of an extinction coefficient k.

O/Si ratio of the phase shift film 2 is preferably 1.16 or more, and more preferably 1.17 or more in view of enhancing a transmittance. On the other hand, O/Si ratio is preferably 1.70 or less, and more preferably 1.69 or less in view of restraining a reduction of a refractive index n.

Further, a ratio of a nitrogen content [atom %] to an oxygen content [atom %] in the phase shift film (hereafter N/O ratio) is preferably 0.12 or more, and more preferably 0.13 or more in view of enhancing a refractive index n. On the other hand, N/O ratio is preferably 0.45 or less, and more preferably 0.44 or less in view of restraining an increase of an extinction coefficient k.

While the phase shift film 2 is preferably a single layer film with a uniform composition, it is not necessarily limited thereto, and can be formed of multiple layers, and can have a configuration with a composition gradient in a thickness direction.

[Light Shielding Film]

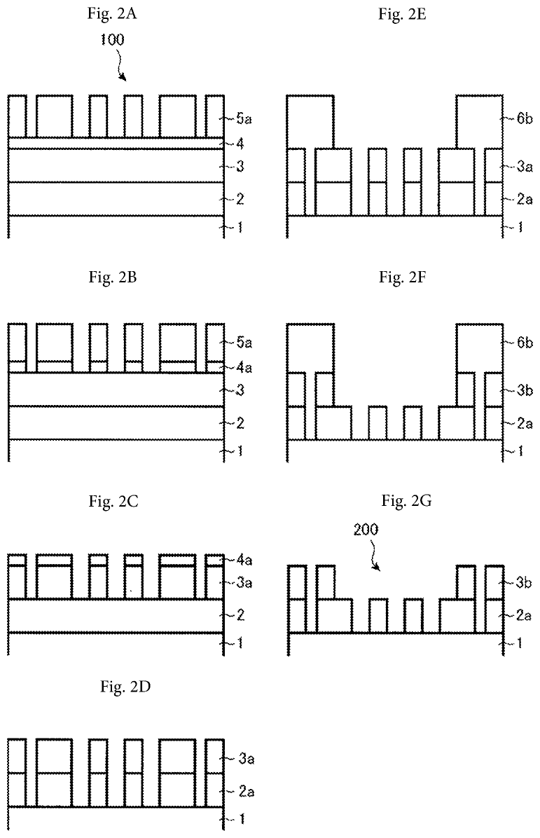

The mask blank 100 has a light shielding film 3 on the phase shift film 2. Generally in a phase shift mask, an outer peripheral region of a region in which a transfer pattern is formed (transfer pattern forming region) is desired to secure optical density (OD) with a predetermined value or more so that a resist film is not affected by an exposure light that transmitted through the outer peripheral region when the resist film on a semiconductor wafer is exposure-transferred using an exposure apparatus. The outer peripheral region of a phase shift mask preferably has OD of 2.8 or more, and more preferably 3.0 or more. As mentioned above, the phase shift film 2 has a function to transmit an exposure light at a transmittance of 70% or more, and it is difficult to secure an optical density of a predetermined value with the phase shift film 2 alone. Therefore, it is necessary to stack the light shielding film 3 on the phase shift film 2 to secure optical density that would otherwise be insufficient at the stage of manufacturing the mask blank 100. With such a configuration of the mask blank 100, the phase shift mask 200 securing a predetermined value of optical density on the outer peripheral region can be manufactured by removing the light shielding film 3 of the region using the phase shifting effect (basically transfer pattern forming region) during manufacture of the phase shift mask 200 (see FIGS. 2A-2G).

A single layer structure and a stacked structure of two or more layers are applicable to the light shielding film 3. Further, each layer in the light shielding film 3 of a single layer structure and the light shielding film 3 with a stacked structure of two or more layers may be configured by approximately the same composition in the thickness direction of the film or the layer, or with a composition gradient in the thickness direction of the layer.

The mask blank 100 of the embodiment shown in FIG. 1 is configured by stacking the light shielding film 3 on the phase shift film 2 without an intervening film. For the light shielding film 3 of this configuration, it is necessary to apply a material having a sufficient etching selectivity to etching gas used in forming a pattern in the phase shift film 2. The light shielding film 3 in this case is preferably formed of a material containing chromium. Materials containing chromium for forming the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, an etching rate of a chromium metal with respect to the etching gas is not so high. Considering enhancing an etching rate of the etching gas formed of mixed gas of chlorine-based gas and oxygen gas, a material forming the light shielding film 3 preferably contains chromium and one or more elements selected from oxygen, nitrogen, carbon, boron, and fluorine. Further, one or more elements among molybdenum, indium, and tin can be included in the material containing chromium for forming the light shielding film 3. Including one or more elements among molybdenum, indium, and tin can further increase an etching rate to mixed gas of chlorine-based gas and oxygen gas.

Incidentally, the mask blank 100 of the present disclosure is not limited to those shown in FIG. 1, but can be configured to have an additional film (etching mask and stopper film) intervening between the phase shift film 2 and the light shielding film 3. In this case, a preferable configuration is that an etching mask and stopper film is formed of the material containing chromium given above, and the light shielding film 3 is formed of a material containing silicon. A material containing silicon for forming the light shielding film 3 can include a transition metal, and can include metal elements other than a transition metal. The reason is that an occurrence of substantial problems is restrained even if ArF light fastness is low because the pattern formed in the light shielding film 3 is basically a light shielding band pattern formed in an outer peripheral region where accumulation of irradiation of an ArF exposure light is less than that in a transfer pattern region, and because a fine pattern is rarely arranged in the outer peripheral region. Another reason is that including a transition metal in the light shielding film 3 significantly enhances light shielding performance compared to the case without a transition metal, which enables a reduction of the thickness of the light shielding film 3. Transition metals to be included in the light shielding film 3 include any one of metals such as molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), and palladium (Pd), or a metal alloy thereof.

On the other hand, the light shielding film 3 can have a structure where a layer consisting of a material containing chromium and a layer consisting of a material containing a transition metal and silicon are stacked, in this order, from the phase shift film 2 side. Concrete matters on the material containing chromium and the material containing a transition metal and silicon in this case are similar to the case of the light shielding film 3 described above.

[Hard Mask Film]

The hard mask film 4 is provided in contact with a surface of the light shielding film 3. The hard mask film 4 is a film formed of a material having etching durability to etching gas used in etching the light shielding film 3. It is sufficient for the hard mask film 4 to have a film thickness that can function as an etching mask until dry etching for forming a pattern in the light shielding film 3 is completed, and the hard mask film 4 is not basically subjected to limitation of optical characteristics. Therefore, a thickness of the hard mask film 4 can be reduced significantly compared to a thickness of the light shielding film 3.

In the case where the light shielding film 3 is formed of a material containing chromium, the hard mask film 4 is preferably formed of a material containing silicon. Since the hard mask film 4 in this case tends to have low adhesiveness with a resist film of an organic material, it is preferable to treat the surface of the hard mask film 4 with HMDS (Hexamethyldisilazane) to enhance surface adhesiveness. The hard mask film 4 in this case is more preferably formed of SiO₂, SiN, SiON, etc.

Further, in the case where the light shielding film 3 is formed of a material containing chromium, materials containing tantalum are also applicable as materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, TaBOCN, etc. Further, in the case where the light shielding film 3 is formed of a material containing silicon, the hard mask film 4 is preferably formed of the material containing chromium given above.

In the mask blank 100, a resist film of an organic material is preferably formed with a film thickness of 100 nm or less in contact with a surface of the hard mask film 4. In the case of a fine pattern to meet DRAM hp32 nm generation, a SRAF (Sub-Resolution Assist Feature) with 40 nm line width may be provided on a transfer pattern (phase shift pattern) to be formed in the hard mask film 4. However, even in this case, the cross-sectional aspect ratio of the resist pattern can be reduced to 1:2.5 so that collapse and peeling of the resist pattern can be prevented in rinsing and developing, etc. of the resist film. Incidentally, the resist film preferably has a film thickness of 80 nm or less.

[Resist Film]

In the mask blank 100, a resist film of an organic material is preferably formed with a film thickness of 100 nm or less in contact with a surface of the hard mask film 4. In the case of a fine pattern compatible with the DRAM hp32 nm generation, SRAF (Sub-Resolution Assist Feature) having a line width of 40 nm may be provided in a light shielding pattern to be formed in the light shielding film 3. However, in this case as well, as described above, a film thickness of the resist film can be controlled to be small as a result of providing the hard mask film 4, and as a consequence, a cross-sectional aspect ratio of the resist pattern formed of the resist film can be set as low as 1:2.5. Therefore, collapse or peeling of the resist pattern during development, rinsing, etc. of the resist film can be restrained. Incidentally, the resist film preferably has a film thickness of 80 nm or less. The resist film is preferably a resist for electron beam writing exposure, and it is more preferable that the resist is a chemically amplified resist.

[Etching Stopper Film]

Although not shown, the mask blank 100 can include an etching stopper film between the transparent substrate 1 and the phase shift film 2. The etching stopper film is desired to have a sufficient etching selectivity between the phase shift film 2 to dry etching when patterning the phase shift film 2. Further, the etching stopper film is desired to have a high transmittance to an exposure light. The etching stopper film is preferably formed of a material containing oxygen and one or more elements selected from aluminum and hafnium. For example, a material containing aluminum, silicon, and oxygen and a material containing aluminum, hafnium, and oxygen are given as materials of the etching stopper film. Particularly, the etching stopper film is preferably formed of a material containing aluminum, hafnium, and oxygen.

Since the etching stopper film can enhance a transmittance to an exposure light and enhance dry etching durability to fluorine-based gas, a ratio by atom % of a hafnium content to a total content of hafnium and aluminum (may hereafter be referred to as Hf/[Hf+Al] ratio) is preferably 0.86 or less, more preferably 0.80 or less, and even more preferably 0.75 or less.

On the other hand, from the viewpoint of resistance to chemical cleaning (esp., alkali cleaning such as ammonium hydrogen peroxide mixture and TMAH), the etching stopper film preferably has Hf/[Hf+Al] ratio of 0.40 or more. Further, from the viewpoint of chemical cleaning using a mixed solution of ammonia water, hydrogen peroxide, and deionized water referred to as SC-1 cleaning, the etching stopper film preferably has Hf/[Hf+Al] ratio of 0.60 or more.

The etching stopper film preferably contains 2 atom % or less of a metal other than aluminum or hafnium, more preferably 1 atom %, and even more preferably equal to detection lower limit or less through composition analysis of X-ray photoelectron spectroscopy. This is because a reduction of a transmittance to an exposure light can be caused when the etching stopper film contains a metal other than aluminum or hafnium. Further, a total content of elements other than aluminum, hafnium, or oxygen of the etching stopper film is preferably 5 atom % or less, and more preferably 3 atom % or less.

The etching stopper film is preferably made of a material consisting of hafnium, aluminum, and oxygen. The material consisting of hafnium, aluminum, and oxygen indicates a material containing, in addition to these constituent elements, only the elements inevitably contained in the etching stopper film when the film is formed by a sputtering method (noble gas such as helium (He), neon (Ne), argon (Ar), krypton (Kr), and xenon (Xe), hydrogen (H), carbon (C), etc.). By minimizing the presence of other elements that bond to hafnium or aluminum in the etching stopper film, a ratio of bonding of hafnium and oxygen, and bonding of aluminum and oxygen in the etching stopper film can be significantly increased. Accordingly, etching durability to dry etching with fluorine-based gas can be further enhanced, resistance to chemical cleaning can be further enhanced, and a transmittance to an exposure light can be further enhanced. The etching stopper film preferably has an amorphous structure. More concretely, the etching stopper film preferably has an amorphous structure in a state including a bond of hafnium and oxygen and a bond of aluminum and oxygen. Thus, a surface roughness of the etching stopper film can be improved, while enhancing a transmittance to an exposure light.

While the etching stopper film preferably has a higher transmittance to an exposure light, since the etching stopper film is simultaneously required to have sufficient etching selectivity to fluorine-based gas between the transparent substrate 1, it is difficult to apply a transmittance to an exposure light that is the same as that of the transparent substrate 1 (i.e., when a transmittance of the transparent substrate 1 (synthetic quartz glass) to an exposure light is 100%, a transmittance of the etching stopper film is less than 100%). A transmittance of the etching stopper film when a transmittance of the transparent substrate 1 to an exposure light is 100% is preferably 85% or more, and more preferably 90% or more.

An oxygen content of the etching stopper film is preferably 60 atom % or more, more preferably 61.5 atom % or more, and even more preferably 62 atom % or more. This is because the etching stopper film is required to contain a large amount of oxygen in order to make a transmittance to an exposure light equal to or greater than the aforementioned value. On the other hand, an oxygen content of the etching stopper film is preferably 66 atom % or less.

A thickness of the etching stopper film is preferably 2 nm or more. Considering the influence of dry etching with fluorine-based gas and the influence of chemical cleaning performed during manufacture of a transfer mask from a mask blank, a thickness of the etching stopper film is more preferably 3 nm or more.

Although the etching stopper film is formed of a material having a high transmittance to an exposure light, a transmittance decreases as a thickness increases. Further, the etching stopper film has a higher refractive index than the material forming the transparent substrate 1, and as a thickness of the etching stopper film increases, the influence on designing a mask pattern (pattern with bias correction, OPC, SRAF, etc.) to be actually formed in the phase shift film 2 increases. Considering these points, the etching stopper film is preferably 10 nm or less, more preferably 8 nm or less, and even more preferably 6 nm or less.

The etching stopper film has a refractive index to an exposure light of preferably 2.90 or less, and more preferably 2.86 or less. This is to reduce the influence in designing a mask pattern to be actually formed in the phase shift film 2. Since the etching stopper film is formed of a material containing hafnium and aluminum, a refractive index n which is the same as that of the transparent substrate 1 cannot be applied. A refractive index of the etching stopper film is preferably 2.10 or more, and more preferably 2.20 or more. On the other hand, an extinction coefficient k to an exposure light of the etching stopper film is preferably 0.30 or less, and more preferably 0.29 or less. This is to enhance a transmittance of the etching stopper film to an exposure light. An extinction coefficient k of the etching stopper film is preferably 0.06 or more.

The etching stopper film preferably has a high uniformity of composition in the thickness direction (difference in content amount of each constituent element in the thickness direction is within a variation width of 5 atom %). On the other hand, the etching stopper film can be formed as a film structure with a composition gradient in the thickness direction. In this case, it is preferable to apply a composition gradient where Hf/[Hf+Al] ratio of the etching stopper film at the transparent substrate 1 side is lower than Hf/[Hf+Al] ratio at the phase shift film 2 side. This is because the etching stopper film is preferentially desired to have higher chemical resistance at the phase shift film 2 side while a higher transmittance to an exposure light is desired at the transparent substrate 1 side.

On the other hand, the etching stopper film can be formed of a material consisting of aluminum, silicon, and oxygen. The etching stopper film preferably contains 2 atom % or less of a metal other than aluminum, more preferably 1 atom % or less, and even more preferably equal to detection lower limit or less through composition analysis of X-ray photoelectron spectroscopy. Further, a total content of elements other than silicon, aluminum, or oxygen of the etching stopper film is preferably 5 atom % or less, and more preferably 3 atom % or less. The etching stopper film is preferably formed of a material containing silicon, aluminum, and oxygen. The material consisting of silicon, aluminum, and oxygen indicates a material containing, in addition to these constituent elements, only the elements inevitably contained in the etching stopper film when the film is formed by a sputtering method (noble gas such as helium (He), neon (Ne), argon (Ar), krypton (Kr), and xenon (Xe), hydrogen (H), carbon (C), etc.).

The etching stopper film preferably has an oxygen content of 60 atom % or more. The etching stopper film preferably has a ratio of a silicon (Si) content [atom %] to a total content of silicon (Si) and aluminum (Al) [atom %] (may hereafter be referred to as “Si/[Si+Al] ratio”) of ⅘ or less. Si/[Si+Al] ratio of the etching stopper film is more preferably ¾ or less, and more preferably ⅔ or less. Si/[Si+Al] ratio of silicon (Si) and aluminum (Al) of the etching stopper film is preferably ⅕ or more.

[Manufacturing Procedure of Mask Blank]

The mask blank 100 of the above configuration is manufactured through the following procedure. First, a transparent substrate 1 is prepared. This transparent substrate includes end surfaces and main surfaces polished into a predetermined surface roughness (e.g., root mean square roughness Rq of 0.2 nm or less in an inner region of a square of 1 μm side), and thereafter subjected to predetermined cleaning treatment and drying treatment.

Next, a phase shift film 2 is formed on the transparent substrate 1 by sputtering method. After the phase shift film 2 is formed, annealing is properly carried out at a predetermined heating temperature. Next, the light shielding film 3 is formed on the phase shift film 2 by sputtering method. Subsequently, the hard mask film 4 is formed on the light shielding film 3 by sputtering method. In film formation by sputtering method, a sputtering target and sputtering gas are used which contain materials forming each film at a predetermined composition ratio, and moreover, the mixed gas of noble gas and reactive gas mentioned above is used as sputtering gas as necessary. Thereafter, in the case where the mask blank 100 includes a resist film, the surface of the hard mask film 4 is subjected to HMDS (Hexamethyldisilazane) treatment as necessary. Next, a resist film is formed by coating methods such as spin coating on the surface of the hard mask film 4 after HMDS treatment to complete the mask blank 100.

In forming the above-mentioned etching stopper film on the mask blank 100, it is preferable to arrange at least one of two targets, i.e., a mixed target of hafnium and oxygen and a mixed target of aluminum and oxygen in a film forming chamber before forming the phase shift film 2 and form the etching stopper film on the transparent substrate 1 by reactive sputtering.

<Manufacturing Method of Phase Shift Mask>

FIGS. 2A-2G show a phase shift mask 200 according to an embodiment of the present disclosure manufactured from the mask blank 100 of the above embodiment, and its manufacturing process. As shown in FIG. 2G, the phase shift mask 200 is featured in that a phase shift pattern 2a as a transfer pattern is formed in a phase shift film 2 of the mask blank 100, and that a light shielding pattern 3b having a pattern including a light shielding band is formed in a light shielding film 3. In the case of a configuration where a hard mask film 4 is provided on the mask blank 100, the hard mask film 4 is removed during manufacture of the phase shift mask 200.

The method of manufacturing the phase shift mask 200 of the embodiment of the present disclosure uses the mask blank 100 mentioned above, in which the method is featured in including the steps of forming a transfer pattern in the light shielding film 3 by dry etching; forming a transfer pattern in the phase shift film 2 by dry etching with the light shielding film 3 including the transfer pattern as a mask; and forming a light shielding pattern 3b in the light shielding film 3 by dry etching with a resist film (resist pattern 6b) including a light shielding pattern as a mask. The method of manufacturing the phase shift mask 200 of the present disclosure is explained below according to the manufacturing steps shown in FIGS. 2A-2G. Explained herein is the method of manufacturing the phase shift mask 200 using the mask blank 100 having the hard mask film 4 stacked on the light shielding film 3. Further, explained herein is the case where a material containing chromium is applied to the light shielding film 3, and a material containing silicon is applied to the hard mask film 4.

First, a resist film is formed in contact with the hard mask film 4 of the mask blank 100 by spin coating. Next, a first pattern, which is a transfer pattern (phase shift pattern) to be formed in the phase shift film 2, was written by exposure with an electron beam on the resist film, and a predetermined treatment such as developing was conducted, to thereby form a first resist pattern 5a having a phase shift pattern (see FIG. 2A). Subsequently, dry etching was conducted using fluorine-based gas with the first resist pattern 5a as a mask, and a first pattern (hard mask pattern 4a) was formed in the hard mask film 4 (see FIG. 2B).

Next, after removing the resist pattern 5a, dry etching was conducted using mixed gas of chlorine-based gas and oxygen gas with the hard mask pattern 4a as a mask, and a first pattern (light shielding pattern 3a) was formed in the light shielding film 3 (see FIG. 2C). Subsequently, dry etching was conducted using fluorine-based gas with the light shielding pattern 3a as a mask, and a first pattern (phase shift pattern 2a) was formed in the phase shift film 2, and also the hard mask pattern 4a was removed (see FIG. 2D).

Next, a resist film was formed on the mask blank 100 by spin coating. Next, a second pattern, which is a pattern (light shielding pattern) to be formed in the light shielding film 3, was written by exposure with an electron beam on the resist film, and a predetermined treatment such as developing was conducted, to thereby form a second resist pattern 6b having a light shielding pattern (see FIG. 2E). Subsequently, dry etching was conducted using a mixed gas of chlorine-based gas and oxygen gas with the second resist pattern 6b as a mask, and a second pattern (light shielding pattern 3b) was formed in the light shielding film 3 (see FIG. 2F). Further, the second resist pattern 6b was removed, predetermined treatments such as cleaning were carried out, and the phase shift mask 200 was obtained (see FIG. 2G).

There is no particular limitation to chlorine-based gas to be used for the dry etching described above, as long as Cl is included. Examples of the chlorine-based gas include Cl₂, SiCl₂, CHCl₃, CH₂Cl₂, CCl₄, BCl₃ and the like. Further, there is no particular limitation to fluorine-based gas to be used for the dry etching described above, as long as F is included. Examples of the fluorine-based gas include CHF₃, CF₄, C₂F₆, C₄F₈, SF₆ and the like. Particularly, fluorine-based gas free of C can further reduce damage on a glass substrate for having a relatively low etching rate to a glass substrate.

The phase shift mask 200 manufactured by the manufacturing method shown in FIGS. 2A-2G is a phase shift mask having a phase shift film 2 (phase shift pattern 2a) having a transfer pattern on the transparent substrate 1.

By manufacturing the phase shift mask 200 as mentioned above, a phase shift mask 200 can be obtained that can enhance a phase shift effect to an exposure light of an ArF excimer laser and that can reduce a film thickness.

Incidentally, a phase shift mask can be manufactured by the method shown in FIGS. 2A-2G using a mask blank including an etching stopper film. In this case, the etching stopper film is left without being removed from the phase shift mask.

Further, the method of manufacturing the semiconductor device of the present disclosure is featured in transferring a transfer pattern to a resist film on a semiconductor substrate by exposure using the phase shift mask 200 given above.

Since the phase shift mask 200 and the mask blank 100 of the present disclosure have the effects as described above, when a transfer pattern is transferred to a resist film on a semiconductor device by exposure after the phase shift mask 200 is set on a mask stage of an exposure apparatus having an ArF excimer laser as an exposure light, a fine transfer pattern can be transferred on the resist film on the semiconductor device. Therefore, in the case where a lower layer film below the resist film was dry etched to form a circuit pattern using the pattern of the resist film as a mask, a highly precise circuit pattern without short-circuit of wiring or disconnection can be formed.

### EXAMPLE 1

Examples 1 to 6 and Comparative Examples 1 to 3 are given below to further concretely describe the embodiments for carrying out the present disclosure.

### Example 1

[Manufacture of Mask Blank]

In view of FIG. 1, a transparent substrate 1 consisting of a synthetic quartz glass with a size of a main surface of about 152 mm×about 152 mm and a thickness of about 6.35 mm was prepared. End surfaces and main surfaces of the transparent substrate 1 were polished to a predetermined surface roughness (0.2 nm or less Rq), and thereafter subjected to predetermined cleaning treatment and drying treatment. Each optical characteristic of the transparent substrate 1 was measured using a spectroscopic ellipsometer (M-2000D manufactured by J. A. Woollam), and a refractive index was 1.556 and an extinction coefficient was 0.000 to a light of 193 nm wavelength.

Next, a transparent substrate 1 was placed in a single-wafer sputtering apparatus, and by reactive sputtering using an Si target with mixed gas of krypton (Kr), oxygen (O₂) gas, and nitrogen (N₂) gas as sputtering gas, a phase shift film 2 consisting of silicon, oxygen, and nitrogen was formed with a thickness of 136.4 nm on the transparent substrate 1 so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 92.0% and a phase difference was 179.9 degrees. Further, each optical characteristic of the phase shift film 2 was measured using a spectroscopic ellipsometer (M-2000D manufactured by J. A. Woollam), and a refractive index n was 1.709 and an extinction coefficient k was 0.005 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=34.5:7.0:58.5 (atom % ratio). N/O ratio was 0.120, 0/Si ratio was 1.696, and N/Si ratio was 0.203. On the other hand, a film density of the phase shift film 2 was calculated using a measuring apparatus utilizing X-ray reflectivity (XRR) (GXR-300 manufactured by Rigaku Corporation), confirming that the film was sufficiently dense.

Next, a transparent substrate 1 was placed in a single-wafer sputtering apparatus, and by reactive sputtering using a chromium (Cr) target with a mixed gas atmosphere of argon (Ar), carbon dioxide (CO₂), and helium (He), a light shielding film 3 consisting of chromium, oxygen, and carbon dioxide (CrOC film: Cr:71 atom %, O:15 atom %, C:14 atom %) was formed with a film thickness of 59 nm in contact with a surface of the phase shift film 2.

Next, the transparent substrate 1 having the light shielding film (CrOC film) 3 formed thereon was subjected to heat treatment. After the heat treatment, a spectrophotometer (Cary4000 manufactured by Agilent Technologies) was used on the transparent substrate 1 having the phase shift film 2 and the light shielding film 3 stacked thereon to measure optical density of the stacked structure of the phase shift film 2 and the light shielding film 3 to an ArF excimer laser light wavelength (about 193 nm), confirming the value of 3.0 or more.

Next, the transparent substrate 1 having the phase shift film 2 and the light shielding film 3 stacked thereon was placed in a single-wafer sputtering apparatus, and by reactive sputtering using silicon dioxide (SiO₂) target and argon (Ar) gas as sputtering gas, a hard mask film 4 containing silicon and oxygen was formed with a thickness of 12 nm on the light shielding film 3. Further, a predetermined cleaning treatment was carried out to form a mask blank 100 of Example 1.

[Manufacture of Phase Shift Mask]

Next, a half tone phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed with a film thickness of 80 nm in contact with a surface of the hard mask film 4 by spin coating. Next, a first pattern, which is a phase shift pattern to be formed in the phase shift film 2, was written by an electron beam on the resist film, predetermined developing and cleaning treatments were conducted, and a resist pattern 5a having the first pattern was formed (see FIG. 2A).

Next, dry etching using CF₄ gas was conducted with the resist pattern 5a as a mask, and a first pattern (hard mask pattern 4a) was formed in the hard mask film 4 (see FIG. 2B).

Next, the resist pattern 5a was removed. Subsequently, dry etching was conducted using mixed gas of chlorine gas (Cl₂) and oxygen gas (O₂) with the hard mask pattern 4a as a mask, and a first pattern (light shielding pattern 3a) was formed in the light shielding film 3 (see FIG. 2C).

Next, dry etching was conducted using fluorine-based gas (CF₄+He) with the light shielding pattern 3a as a mask, and a first pattern (phase shift pattern 2a) was formed in the phase shift film 2, and also the hard mask pattern 4a was removed (see FIG. 2D).

Next, a resist film of a chemically amplified resist for electron beam writing was formed with a film thickness of 150 nm on the light shielding pattern 3a by spin coating. Next, a second pattern, which is a pattern (pattern including light shielding band pattern) to be formed in the light shielding film, was written by exposure on the resist film, further predetermined treatments such as developing were carried out to form a resist pattern 6b having the light shielding pattern (see FIG. 2E). Subsequently, dry etching was conducted using mixed gas of chlorine gas (Cl₂) and oxygen gas (O₂) with the resist pattern 6b as a mask, and a second pattern (light shielding pattern 3b) was formed in the light shielding film 3 (see FIG. 2F). Further, the resist pattern 6b was removed, predetermined treatments such as cleaning were carried out, and the phase shift mask 200 was obtained (see FIG. 2G).

[Evaluation of Pattern Transfer Performance]

On the phase shift mask 200 manufactured by the above procedures, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specification was fully satisfied without short-circuit of wiring or disconnection. It can be considered from this result that a circuit pattern to be finally formed on the semiconductor device can be formed at a high precision when the phase shift mask 200 of Example 1 is set on a mask stage of an exposure apparatus and a resist film on the semiconductor device is subjected to exposure transfer.

### Example 2

[Manufacture of Mask Blank]

A mask blank 100 of Example 2 was manufactured through the same procedure as Example 1, except for the phase shift film 2. The phase shift film 2 of Example 2 has film forming conditions different from that of the phase shift film 2 of Example 1. Concretely, a transparent substrate 1 was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film 2 consisting of silicon, oxygen, and nitrogen was formed with a thickness of 128.7 nm on the transparent substrate 1 so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 89.5% and a phase difference was 179.7 degrees. Further, each optical characteristic of the phase shift film 2 was measured using a spectroscopic ellipsometer (M-2000D manufactured by J. A. Woollam), and a refractive index n was 1.750 and an extinction coefficient k was 0.009 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:0=34.6:8.8:56.6 (atom % ratio). N/O ratio was 0.155, 0/Si ratio was 1.636, and N/Si ratio was 0.254. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank 100 of Example 2, a phase shift mask 200 of Example 2 was manufactured through the same procedure as Example 1. On the phase shift mask 200 of Example 2, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was fully satisfied without short-circuit of wiring or disconnection. It can be considered from this result that a circuit pattern to be finally formed on the semiconductor device can be formed at a high precision when the phase shift mask 200 of Example 2 is set on a mask stage of an exposure apparatus and a resist film on the semiconductor device is subjected to exposure transfer.

### Example 3

[Manufacture of Mask Blank]

A mask blank 100 of Example 3 was manufactured through the same procedure as Example 1, except for the phase shift film 2. The phase shift film 2 of Example 3 has film forming conditions different from that of the phase shift film 2 of Example 1. Concretely, a transparent substrate 1 was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film 2 consisting of silicon, oxygen, and nitrogen was formed with a thickness of 108.7 nm on the transparent substrate 1 so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 80.9% and a phase difference was 181.3 degrees. Further, each optical characteristic of the phase shift film 2 was measured using a spectroscopic ellipsometer (M-2000D manufactured by J. A. Woollam), and a refractive index n was 1.890 and an extinction coefficient k was 0.026 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=35.9:14.8:49.3 (atom % ratio). N/O ratio was 0.300, 0/Si ratio was 1.373, and N/Si ratio was 0.412. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank 100 of Example 3, a phase shift mask 200 of Example 3 was manufactured through the same procedure as Example 1. On the phase shift mask 200 of Example 3, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was fully satisfied without short-circuit of wiring or disconnection. It can be considered from this result that a circuit pattern to be finally formed on the semiconductor device can be formed with high precision when the phase shift mask 200 of Example 3 is set on a mask stage of an exposure apparatus and a resist film on the semiconductor device is subjected to exposure transfer.

### Example 4

[Manufacture of Mask Blank]

A mask blank 100 of Example 4 was manufactured through the same procedure as Example 1, except for the phase shift film 2. The phase shift film 2 of Example 4 has film forming conditions different from that of the phase shift film 2 of Example 1. Concretely, a transparent substrate 1 was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film 2 consisting of silicon, oxygen, and nitrogen was formed with a thickness of 100.1 nm on the transparent substrate 1 so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 75.4% and a phase difference was 181.3 degrees. Further, each optical characteristic of the phase shift film 2 was measured using a spectroscopic ellipsometer (M-2000D manufactured by J. A. Woollam), and a refractive index n was 1.973 and an extinction coefficient k was 0.039 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=36.9:18.4:44.7 (atom % ratio). N/O ratio was 0.412, 0/Si ratio was 1.211, and N/Si ratio was 0.499. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank 100 of Example 4, a phase shift mask 200 of Example 4 was manufactured using the same procedure as Example 1. On the phase shift mask 200 of Example 4, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was fully satisfied without short-circuit of wiring or disconnection. It can be considered from this result that a circuit pattern to be finally formed on the semiconductor device can be formed at a high precision when the phase shift mask 200 of Example 4 is set on a mask stage of an exposure apparatus and a resist film on the semiconductor device is subjected to exposure transfer.

### Example 5

[Manufacture of Mask Blank]

A mask blank 100 of Example 5 was manufactured through the same procedure as Example 1, except for the phase shift film 2. The phase shift film 2 of Example 5 has film forming conditions different from that of the phase shift film 2 of Example 1. Concretely, a transparent substrate 1 was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film consisting of silicon, oxygen, and nitrogen was formed with a thickness of 98.2 nm on the transparent substrate so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 74.0% and a phase difference was 181.7 degrees. Further, each optical characteristic of the phase shift film 2 was measured using a spectroscopic ellipsometer (M-2000D manufactured by J. A. Woollam), and a refractive index n was 1.994 and an extinction coefficient k was 0.043 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=37.3:19.4:43.3 (atom % ratio). N/O ratio was 0.448, 0/Si ratio was 1.161, and N/Si ratio was 0.520. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank 100 of Example 5, a phase shift mask 200 of Example 5 was manufactured through the same procedure as Example 1. On the phase shift mask 200 of Example 5, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was fully satisfied without short-circuit of wiring or disconnection. It can be considered from this result that a circuit pattern to be finally formed on the semiconductor device can be formed at a high precision when the phase shift mask 200 of Example 5 is set on a mask stage of an exposure apparatus and a resist film on the semiconductor device is subjected to exposure transfer.

### Example 6

[Manufacture of Mask Blank]

A mask blank 100 of Example 6 was manufactured through the same procedure as Example 3, except for the film thickness of the phase shift film 2. With regard to the phase shift film 2 of Example 6, a reactive sputtering was conducted under the same film forming conditions as that of the phase shift film 2 of Example 3. Through the above procedure, a phase shift film 2 consisting of silicon, oxygen, and nitrogen was formed with a thickness of 125.0 nm on the transparent substrate 1 so that a desired phase difference can be obtained.

A transmittance and a phase difference of the phase shift film 2 to a light of 193 nm wavelength were measured using a phase shift measurement apparatus (MPM193 manufactured by Lasertec), and a transmittance was 73.2% and a phase difference was 205.1 degrees. Further, each optical characteristic of the phase shift film 2 was measured using a spectroscopic ellipsometer (M-2000D manufactured by J. A. Woollam), and a refractive index n was 1.890 and an extinction coefficient k was 0.026 in a light of 193 nm wavelength. The composition, N/O ratio, O/Si ratio, and N/Si ratio of the phase shift film were identical to Example 3. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank 100 of Example 6, a phase shift mask 200 of Example 6 was manufactured through the same procedure as that of Example 1. On the phase shift mask 200 of Example 6, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was fully satisfied without short-circuit of wiring or disconnection. It can be considered from this result that a circuit pattern to be finally formed on the semiconductor device can be formed at a high precision when the phase shift mask 200 of Example 6 is set on a mask stage of an exposure apparatus and a resist film on the semiconductor device is subjected to exposure transfer.

### Comparative Example 1

[Manufacture of Mask Blank]

A mask blank of Comparative Example 1 was manufactured by the same procedure as Example 1, except for the phase shift film. The phase shift film of Comparative Example 1 has film forming conditions different from that of the phase shift film 2 of Example 1. Concretely, a transparent substrate was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film consisting of silicon, oxygen, and nitrogen was formed with a thickness of 143.1 nm on the transparent substrate so that a desired phase difference can be obtained.

A transmittance and a phase difference of the phase shift film to a light of 193 nm wavelength were measured using a phase shift measurement apparatus (MPM193 manufactured by Lasertec), and a transmittance was 93.8% and a phase difference was 180.5 degrees. Further, each optical characteristic of the phase shift film was measured using a spectroscopic ellipsometer (M-2000D manufactured by J. A. Woollam), and a refractive index n was 1.676 and an extinction coefficient k was 0.003 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=34.2:5.5:60.3 (atom % ratio). N/O ratio was 0.091, 0/Si ratio was 1.763, and N/Si ratio was 0.161. On the other hand, a film density of the phase shift film was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank of Comparative Example 1, the phase shift mask of Comparative Example 1 was manufactured through the same procedure as that of Example 1. On the phase shift mask of Comparative Example 1, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was not satisfied, with an occurrence of short-circuit of wiring and disconnection. This result is inferred as caused by an occurrence of collapse and falling-off of a part of the pattern of the phase shift film. It can be considered from this result that a circuit pattern to be finally formed on the semiconductor device can hardly be formed at a high precision when the phase shift mask of Comparative Example 1 is set on a mask stage of an exposure apparatus and a resist film on the semiconductor device is subjected to exposure transfer.

### Comparative Example 2

[Manufacture of Mask Blank]

A mask blank of Comparative Example 2 was manufactured through the same procedure as that of Example 1, except for the phase shift film and a film thickness of the light shielding film. The phase shift film of Comparative Example 2 has film forming conditions different from that of the phase shift film 2 of Example 1. Concretely, a transparent substrate was placed in a single-wafer sputtering apparatus, and reactive sputtering was conducted using an Si target, with krypton gas, oxygen gas, and nitrogen gas as sputtering gas with the gas flow rate of oxygen gas and nitrogen gas having been changed. Through the above procedure, a phase shift film consisting of silicon, oxygen, and nitrogen was formed with a thickness of 92.2 nm on the transparent substrate so that a desired phase difference can be obtained.

A transmittance and a phase difference of the phase shift film to a light of 193 nm wavelength were measured using a phase shift measurement apparatus (MPM193 manufactured by Lasertec), and a transmittance was 68.5% and a phase difference was 184.9 degrees. Further, each optical characteristic of the phase shift film was measured using a spectroscopic ellipsometer (M-2000D manufactured by J. A. Woollam), and a refractive index n was 2.077 and an extinction coefficient k was 0.058 in a light of 193 nm wavelength. A phase shift film was formed on another transparent substrate under the same film forming conditions. Further, the phase shift film was subjected to an X-ray photoelectron spectroscopy analysis (XPS analysis). As a result, the composition of the phase shift film was Si:N:O=37.5:22.5:40.0 (atom % ratio). N/O ratio was 0.563, 0/Si ratio was 1.067, and N/Si ratio was 0.600. On the other hand, a film density of the phase shift film was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank of Comparative Example 2, a phase shift mask of Comparative Example 2 was manufactured through the same procedure as that of Example 1. On the phase shift mask of Comparative Example 2, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was not satisfied. This result is inferred as caused by a significant reduction of pattern resolution by failure to sufficiently increase a transmittance of the phase shift film. It can be considered from this result that a circuit pattern to be finally formed on the semiconductor device can hardly be formed at a high precision when the phase shift mask of Comparative Example 2 is set on a mask stage of an exposure apparatus and a resist film on the semiconductor device is subjected to exposure transfer.

### Comparative Example 3

[Manufacture of Mask Blank]

A mask blank of Comparative Example 3 was manufactured by the same procedure as that of Example 1, except for a phase shift film. The phase shift film of Comparative Example 3 has film forming conditions different from that of the phase shift film 2 of Example 1. Concretely, a transparent substrate was placed in a single-wafer sputtering apparatus, and reactive sputtering was conducted using an Si target, without nitrogen gas, and using oxygen gas and krypton gas as sputtering gas. Through the above procedure, a phase shift film consisting of silicon and oxygen was formed with a thickness of 172.7 nm on the transparent substrate.

A transmittance and a phase difference of the phase shift film to a light of 193 nm wavelength were measured using a phase shift measurement apparatus (MPM193 manufactured by Lasertec), and a transmittance was 100.0% and a phase difference was 180.4 degrees. Further, each optical characteristic of the phase shift film was measured using a spectroscopic ellipsometer (M-2000D manufactured by J. A. Woollam), and a refractive index n was 1.560 and an extinction coefficient k was 0.000 in a light of 193 nm wavelength. A phase shift film was formed on another transparent substrate under the same film forming conditions. The composition of the phase shift film was Si:O=33.4:66.6 (atom % ratio). N/O ratio was 0.000, 0/Si ratio was 1.994, and N/Si ratio was 0.000. On the other hand, a film density of the phase shift film 2 was calculated using a measuring apparatus utilizing X-ray reflectivity (XRR) (GXR-300 manufactured by Rigaku Corporation), confirming that the film was sufficiently dense.

[Manufacture and Evaluation of Phase Shift Mask]

Next, using the mask blank of Comparative Example 3, a phase shift mask of Comparative Example 3 was manufactured through the same procedure as that of Example 1. On the phase shift mask of Comparative Example 3, a simulation of a transfer image was made using AIMS193 (manufactured by Carl Zeiss) assuming that an exposure transfer was made on a resist film on a semiconductor device at an exposure light of 193 nm wavelength, similar to Example 1. The simulated exposure transfer image was inspected, and the design specification was not satisfied, with an occurrence of short-circuit of wiring and disconnection. This result is inferred as caused by an occurrence of collapse and falling-off of a part of the pattern of the phase shift film. It can be considered from this result that a circuit pattern to be finally formed on the semiconductor device can hardly be formed at a high precision when the phase shift mask of Comparative Example 3 is set on a mask stage of an exposure apparatus and a resist film on the semiconductor device is subjected to exposure transfer.

### DESCRIPTION OF REFERENCE NUMERALS

1. transparent substrate
2. phase shift film
2a. phase shift pattern
3. light shielding film
3a,3b. light shielding pattern
4. hard mask film
4a. hard mask pattern
5a. resist pattern
6b. resist pattern
100. mask blank
200. phase shift mask

1. A mask blank comprising a phase shift film on a main surface of a transparent substrate,
wherein the phase shift film contains silicon, oxygen, and nitrogen,
wherein a ratio of a nitrogen content [atom %] to a silicon content [atom %] of the phase shift film is 0.20 or more and 0.52 or less,
wherein a ratio of an oxygen content [atom %] to a silicon content [atom %] of the phase shift film is 1.16 or more and 1.70 or less,
wherein a refractive index n of the phase shift film to a wavelength of an exposure light of an ArF excimer laser is 1.7 or more and 2.0 or less,
wherein an extinction coefficient k of the phase shift film to the wavelength of the exposure light is 0.05 or less, and
wherein the phase shift film has a function to transmit the exposure light at a transmittance of 70% or more, and a function to generate a phase difference of 150 degrees or more and 210 degrees or less between the exposure light transmitted through the phase shift film and an exposure light transmitted through the air for a same distance as a thickness of the phase shift film.

2. The mask blank according to claim 1, wherein a ratio of nitrogen content [atom %] to an oxygen content [atom %] of the phase shift film is 0.12 or more and 0.45 or less.

3. The mask blank according to claim 1, wherein a silicon content of the phase shift film is 30 atom % or more.

4. (canceled)

5. The mask blank according to claim 1, wherein the phase shift film has a thickness of 140 nm or less.

6. The mask blank according to claim 1 comprising a light shielding film on the phase shift film.

7. A phase shift mask comprising a phase shift film having a transfer pattern on a main surface of a transparent substrate,
wherein the phase shift film contains silicon, oxygen, and nitrogen,
wherein a ratio of a nitrogen content [atom %] to a silicon content [atom %] of the phase shift film is 0.20 or more and 0.52 or less,
wherein a ratio of an oxygen content [atom %] to a silicon content [atom %] of the phase shift film is 1.16 or more and 1.70 or less,
wherein a refractive index n of the phase shift film to a wavelength of an exposure light of an ArF excimer laser is 1.7 or more and 2.0 or less, and
wherein an extinction coefficient k of the phase shift film to the wavelength of the exposure light is 0.05 or less, and
wherein the phase shift film has a function to transmit the exposure light at a transmittance of 70% or more, and a function to generate a phase difference of 150 degrees or more and 210 degrees or less between the exposure light transmitted through the phase shift film and an exposure light transmitted through the air for a same distance as a thickness of the phase shift film.

8. The phase shift mask according to claim 7, wherein a ratio of a nitrogen content [atom %] to an oxygen content [atom %] of the phase shift film is 0.12 or more and 0.45 or less.

9. The phase shift mask according to claim 7, wherein the phase shift film has a silicon content of 30 atom % or more.

10. (canceled)

11. The phase shift mask according to claim 7, wherein the phase shift film has a thickness of 140 nm or less.

12. The phase shift mask according to claim 7 comprising a light shielding film having a pattern with a light shielding band on the phase shift film.

13. A method of manufacturing a semiconductor device including a step of transferring a transfer pattern to a resist film on a semiconductor substrate by exposure using the phase shift mask according to claim 12.

14. The phase shift mask according to claim 8, wherein the phase shift film has a silicon content of 30 atom % or more.

15. The phase shift mask according to claim 14, wherein the phase shift film has a thickness of 140 nm or less.

16. The phase shift mask according to claim 15 comprising a light shielding film having a pattern with a light shielding band on the phase shift film.

17. The mask blank according to claim 2, wherein a silicon content of the phase shift film is 30 atom % or more.

18. The mask blank according to claim 17, wherein the phase shift film has a thickness of 140 nm or less.

19. The mask blank according to claim 18 comprising a light shielding film on the phase shift film.
